(19) United States
(12) Patent Application Publication
(10) Pub. No.: US 2016/0020577 A1
(43) Pub. Date: Jan. 21, 2016

(54) SEMICONDUCTOR LASER DEVICE

(71) Applicant: ROHM CO., LTD., Kyoto-shi (JP)

(72) Inventor: Kenji SAKAI, Kyoto-shi (JP)

(21) Appl. No.: 14/798,889

(22) Filed: Jul. 14, 2015

(30) Foreign Application Priority Data
Jul. 15, 2014 (JP) 2014-145160
Jul. 13, 2015 (JP) 2015-139653

(51) Int. Cl. H01S 5/022

(52) U.S. Cl. CPC H01S 5/02244; H01S 5/02296

(57) ABSTRACT

A semiconductor laser device includes a semiconductor laser chip configured to emit laser light forward in the emission direction and a stem having a tabular base whose thickness direction is in the emission direction. The base has a chip through-hole that passes through in the thickness direction. A part of the semiconductor laser chip is accommodated in the chip through-hole.

### BACKGROUND OF THE INVENTION

1. Field of the Invention

The present invention relates to a semiconductor laser device.

2. Description of Related Art

Semiconductor laser devices are widely employed as light source devices that are mounted in various electronic devices. JP-A-2004-31900 discloses an example of a conventional semiconductor laser device. The semiconductor laser device disclosed in JP-A-2004-31900 is provided with a stem, a semiconductor laser chip, a plurality of leads, and a cap. The stem is made of a metal material and has a tabular base and a block projecting forward in an emission direction from the base. The semiconductor laser chip is mounted on the block. The block projects forward in the direction in which light is emitted from the semiconductor laser chip. The plurality of leads are fixed to the stem, and each extends backward in the emission direction. The cap covers the block and the semiconductor laser chip, and has an opening that allows light from the semiconductor laser chip to pass. According to such a configuration, when power is switched on via the plurality of leads, light from the semiconductor laser chip is emitted forward in the emission direction.

However, attempts to increase the luminance, that is, output, of the semiconductor laser device result in a corresponding increase in the size of the semiconductor laser chip. In particular, this increase in size typically involves an increase in the dimensions of the semiconductor laser chip in the emission direction. The projection dimensions of the semiconductor laser chip and the block from the base thus increase, and give rise to an increase in the size of the semiconductor laser device.

### SUMMARY OF THE INVENTION

The present invention has been proposed under the above circumstances, and has a main object to provide a semiconductor laser device that enables higher output and miniaturization to be achieved.

According to the present invention, a semiconductor laser device including a semiconductor laser chip configured to emit laser light forward in an emission direction and a stem having a tabular base a thickness direction of which is in the emission direction is provided. The base is formed with a chip through-hole that passes through in the thickness direction, and a part of the semiconductor laser chip is accommodated in the chip through-hole.

Preferably, the stem has a block projecting in the emission direction from the base, and the semiconductor laser chip is supported by the block.

Preferably, a forward end of the semiconductor laser chip in the emission direction is located further backward in the emission direction than a forward end of the block in the emission direction.

Preferably, a backward end of the semiconductor laser chip in the emission direction is located further forward in the emission direction than a backward end of the chip through-hole in the emission direction.

Preferably, the base and the block are integrally formed with each other.

Preferably, the base and the block are made of Fe or Fe alloy.

Preferably, the base and the block are formed as separate elements.

Preferably, the base is made of Fe or Fe alloy.

Preferably, the block is made of Cu or Cu alloy.

Preferably, the block has a supporting surface that supports the semiconductor laser chip.

Preferably, the supporting surface is parallel to the emission direction.

Preferably, the chip through-hole has a rectangular shape as seen in the emission direction.

Preferably, an inner surface of the chip through-hole is flush with the supporting surface.

Preferably, the semiconductor laser chip is joined to the stem by a joining material.

Preferably, the semiconductor laser chip is joined to the supporting surface of the block by the joining material.

Preferably, the semiconductor laser chip is joined to the inner surface of the chip through-hole by the joining material.

Preferably, the semiconductor laser chip is made up of a semiconductor element made of a semiconductor material and a submount on which the semiconductor element is mounted.

Preferably, the submount is made of Si or AlN.

Preferably, the semiconductor laser device includes one or more leads that are supported by the stem, project backward in the emission direction, and are electrically connected to the semiconductor laser chip.

Preferably, the base has a lead through-hole through which the lead is inserted.

Preferably, an insulating filler fills a space between the lead through-hole and the lead.

Preferably, the insulating filler is made of glass.

Preferably, the lead is made of Fe—Ni alloy or Fe—Ni—Co alloy.

Preferably, the lead is Au plated.

Preferably, the semiconductor laser device includes a wire electrically connecting the lead to the semiconductor laser chip.

Preferably, the wire is made of Au.

Preferably, the semiconductor laser device includes a cap that is fixed to the base, covers the semiconductor laser chip, and has an opening that allows light from the semiconductor laser chip to pass.

Preferably, the cap has a body part surrounding the semiconductor laser chip in a direction at a right-angle to the emission direction, and a top part connected to a forward portion of the body part in the emission direction.

Preferably, the cap has a flange part that is connected to a backward portion of the body part in the emission direction and is fixed to the base.

Preferably, the opening is formed in the top part.

Preferably, the cap is provided with a cover that closes the opening and through which light from the semiconductor laser chip passes.

Preferably, the cover is transparent.

Preferably, the cover transmits and diffuses light from the semiconductor laser chip.

Other features and advantages of the present invention will become apparent from the following detailed description with reference to the accompanying drawings.

### BRIEF DESCRIPTION OF THE DRAWINGS

FIG. 1 is a perspective view showing a semiconductor laser device that is based on a first embodiment of the present invention.

FIG. 2 is a plan view showing the semiconductor laser device of FIG. 1.

FIG. 3 is a cross-sectional view along a line III-III in FIG. 2.

FIG. 4 is a cross-sectional view along a line IV-IV in FIG. 2.

FIG. 5 is an enlarged cross-sectional view showing a main section of the semiconductor laser device of FIG. 1.

FIG. 6 is a plan view showing a modification of the semiconductor laser device of FIG. 1.

FIG. 7 is a plan view showing another modification of the semiconductor laser device of FIG. 1.

FIG. 8 is a cross-sectional view showing a semiconductor laser device that is based on a second embodiment of the present invention.

FIG. 9 is a cross-sectional view showing the semiconductor laser device of FIG. 8.

FIG. 10 is a cross-sectional view showing a semiconductor laser device that is based on a third embodiment of the present invention.

FIG. 11 is an enlarged cross-sectional view showing a main section of the semiconductor laser device of FIG. 10.

FIG. 12 is a plan view showing a semiconductor laser device that is based on a fourth embodiment of the present invention.

FIG. 13 is a cross-sectional view along a line XIII-XIII in FIG. 12.

FIG. 14 is an enlarged cross-sectional view showing a main section of the semiconductor laser device of FIG. 12.

FIG. 15 is a cross-sectional view showing a semiconductor laser device that is based on a fifth embodiment of the present invention.

FIG. 16 is a cross-sectional view showing a semiconductor laser device that is based on a sixth embodiment of the present invention.

FIG. 17 is a perspective view showing a semiconductor laser device that is based on a seventh embodiment of the present invention.

FIG. 18 is a cross-sectional view showing a semiconductor laser device that is based on an eighth embodiment of the present invention.

FIG. 19 is a cross-sectional view showing a semiconductor laser device that is based on a ninth embodiment of the present invention.

FIG. 20 is a cross-sectional view showing a semiconductor laser device that is based on a tenth embodiment of the present invention.

FIG. 21 is a cross-sectional view showing a semiconductor laser device that is based on an eleventh embodiment of the present invention.

FIG. 22 is a plan view showing a main section of a modification of the chip through-hole.

FIG. 23 is a plan view showing a main section of another modification of the chip through-hole.

FIG. 24 is a plan view showing a main section of another modification of the chip through-hole.

### DESCRIPTION OF THE PREFERRED EMBODIMENTS

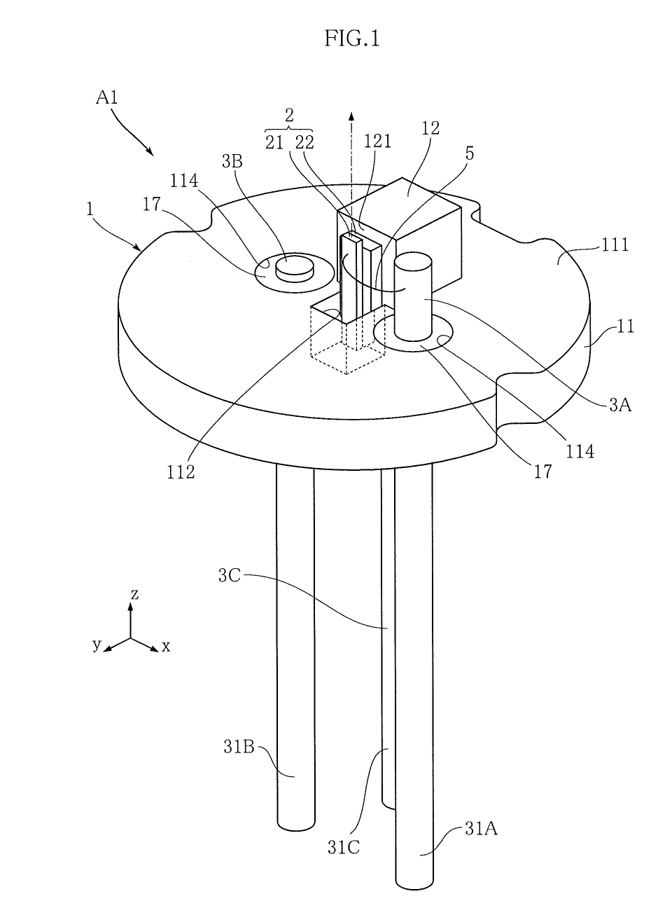

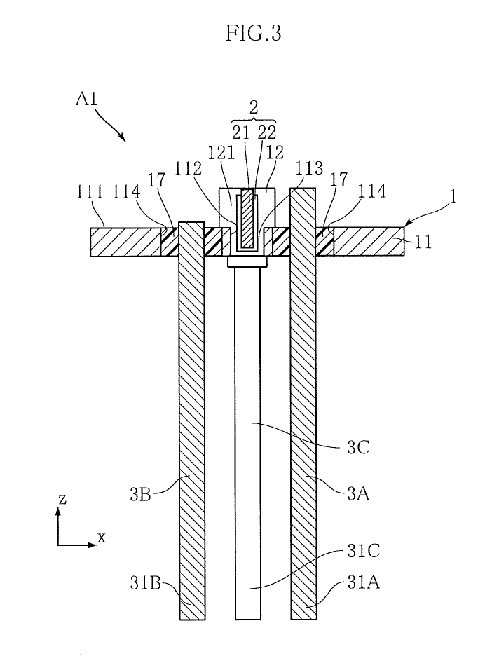

FIGS. 1 to 5 show a semiconductor laser device that is based on a first embodiment of the present invention. A semiconductor laser device A1 of the present embodiment is provided with a stem 1, a semiconductor laser chip 2, a plurality of leads 3A, 3B and 3C, and a wire 5. The semiconductor laser device A1 can be used as a light source in various electronic devices, and is suited to application as a compact light source device that is mounted in a mobile phone or a portable notebook PC, for example. A z direction in the figures corresponds to an emission direction of the semiconductor laser chip 2. An x direction and a y direction are respectively directions at right-angles to the z direction. Note that, in FIGS. 3 to 5, the wire 5 is omitted to facilitate understanding.

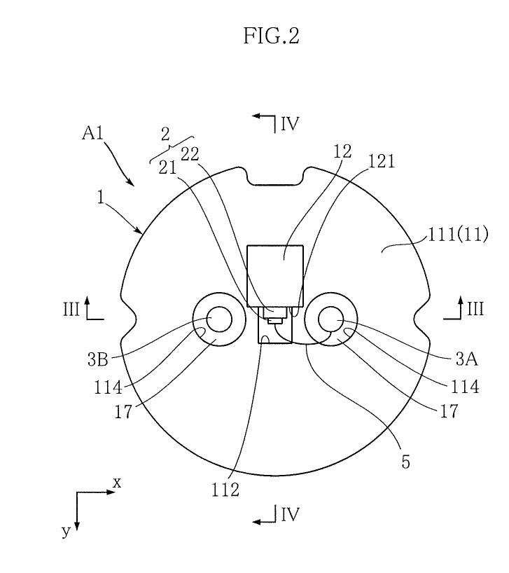

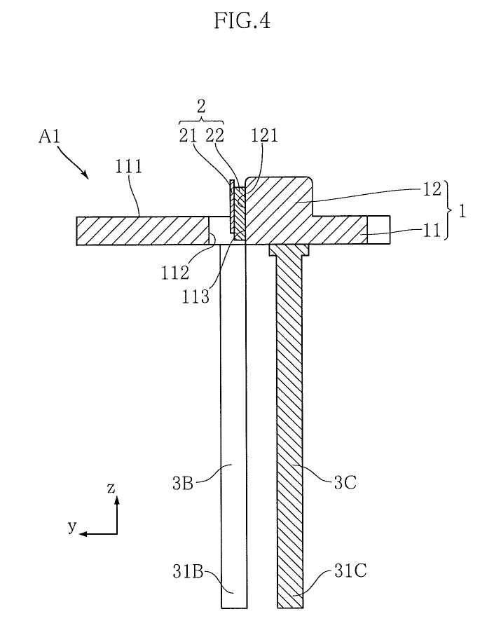

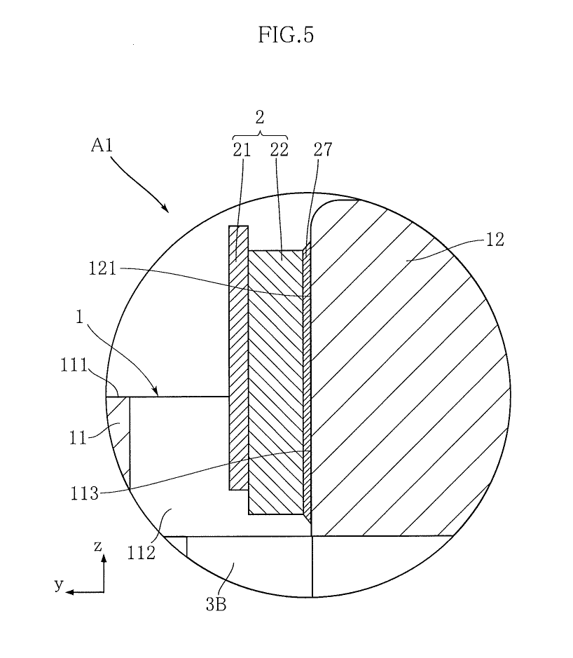

FIG. 1 is a perspective view showing the semiconductor laser device A1. FIG. 2 is a plan view showing the semiconductor laser device A1. FIG. 3 is a cross-sectional view along a line III-III in FIG. 2. FIG. 4 is a cross-sectional view along a line IV-IV in FIG. 2, and FIG. 5 is an enlarged cross-sectional view of a main section.

The stem 1 serves as a base of the semiconductor laser device A1, and has a base 11 and a block 12. In the stem 1 of the present embodiment, the base 11 and the block 12 are integrally formed. The stem 1 is not particularly limited in terms of material, and is made of Fe or Fe alloy, for example. Also, Ni plating, Cu plating, Au plating or the like having a thickness of about 2 to 4 μm may be performed on the Fe or Fe alloy.

The base 11 is a tabular region whose thickness direction is in the z direction, and, in the present embodiment, has a substantially circular shape as seen in the z direction. The base 11 has a main surface 111 that faces forward in the z direction. To give an example of the dimensions of the base 11, the diameter is about 5.6 mm and the thickness is about 0.5 mm.

A chip through-hole 112 and two lead through-holes 114 are formed in the base 11. The chip through-hole 112 passes through the base 11 in the z direction. In the present embodiment, the chip through-hole 112 overlaps with the center of the base 11 as seen in the z direction, and has a rectangular shape as seen in the z direction. The four sides of the chip through-hole 112 in plan view lie in one of the x direction and the y direction. An inner surface 113 of the inner surfaces of the chip through-hole 112 is a surface whose normal direction is in the y direction. To give an example of the size of the chip through-hole 112, the dimensions are about 0.6 mm in the x direction and about 0.65 mm in the y direction as seen in the z direction. The lead through-holes 114 are not particularly limited in terms of shape and size, and, in the present embodiment, are circular through-holes having a diameter of about 0.95 mm. The diameter of the lead through-holes 114 is set as appropriate according to the sizes of the base 11 and the leads 3A and 3b, the interval between the lead 3A and the lead 3B, and the like.

Two lead through-holes 114 are formed in order to fix the lead 3A and the lead 3B to the base 11 of the stem 1. As shown in FIG. 2, the two lead through-holes 114 are formed on both sides of the chip through-hole 112 in the x direction. The lead through-holes 114 pass through the base 11 in the z direction. The lead through-holes 114 are not particularly limited in terms of shape, and, in the present embodiment, the lead through-holes 114 have a circular shape as seen in the z direction.

The block 12 projects forward in the z direction (upward in the figures) from the main surface 111 of the base 11. The block 12 is not particularly limited in terms of shape, and, in the present embodiment, the block 12 has a rectangular parallelepiped shape. The block 12 has a supporting surface 121. The supporting surface 121 is the surface to which the semiconductor laser chip 2 is mounted, and, in the present embodiment, is parallel to the z direction. Also, as shown in FIG. 5, the supporting surface 121 of the block 12 and the inner surface 113 of the chip through-hole 112 in the base 11 are flush with each other. To give an example of the size of the block 12, the dimensions are about 1.0 mm in the x direction, about 1.1 mm in the y direction, and about 0.7 mm in the z direction.

The semiconductor laser chip 2 is a light-emitting element of the semiconductor laser device A1. In the present embodiment, the semiconductor laser chip 2 is made up of a semiconductor element 21 and a submound 22. Note that the semiconductor laser chip 2 is not limited to this configuration, and may, for example, be configured to not have the submound 22 and only be composed of the semiconductor element 21. In the present invention, the semiconductor laser chip 2 indicates an element that is mounted on the supporting surface 121, for example, of the stem 1, and is, in the case where the submound 22 is employed, defined as an element including the submound 22. To give an example of the dimensions of the semiconductor laser chip 2, the dimensions are about 1.1 mm in the z direction, about 0.4 mm in the x direction, and about 0.17 to 0.27 mm in the y direction. More specifically, the dimensions of the submound 22 are about 1.0 mm in the z direction, about 0.4 mm in the x direction, and about 0.1 to 0.2 mm in the y direction. The dimensions of the semiconductor element 21 are about 1.0 mm in the z direction, about 0.22 mm in the x direction, and about 0.07 mm in the y direction. Note that the forward end of the semiconductor element 21 in the z direction projects further forward in the z direction than the forward end of the submound 22 in the z direction. In the present embodiment, the forward end of the semiconductor element 21 in the z direction is, however, located further backward in the z direction than the forward end of the block 12 in the z direction.

The semiconductor element 21 has a structure in which a plurality of semiconductor layers are laminated. The semiconductor element 21 has an elongated shape in the z direction. Light is emitted forward in the z direction from the semiconductor element 21. The submound 22 supports the semiconductor element 21, and is joined to the supporting surface 121 of the block 12 of the stem 1. The submound 22 is made of Si or AlN, for example. Also, in the present embodiment, an electrical connection path (not shown) such as a wiring pattern or a through-hole electrode for electrically connecting the semiconductor element 21 to the block 12 is formed on the submound 22.

As shown in FIG. 5, part of the semiconductor laser chip 2 that is on the backward side in the z direction is accommodated in the chip through-hole 112. Furthermore, the forward end of the semiconductor laser chip 2 in the z direction is located further backward in the z direction than the forward end of the block 12 of the stem 1 in the z direction. Also, the backward end of the semiconductor laser chip 2 in the z direction is located further forward in the z direction than the backward end of the chip through-hole 112 of the base 11 of the stem 1 in the z direction.

As shown in FIG. 5, the submound 22 of the semiconductor laser chip 2 is joined to the stem 1 by a joining material 27. In the present embodiment, the supporting surface 121 of the block 12 is flush with the inner surface 113 of the chip through-hole 112. The submound 22 of the semiconductor laser chip 2 is joined to both the supporting surface 121 and the inner surface 113 by the joining material 27. The joining material 27 is not particularly limited as long as the semiconductor laser chip 2 can be appropriately joined thereto, and may be solder or a metal paste containing Ag, In, Au, Sn or the like, for example. Note that, in the present embodiment, a conductive material is employed as the joining material 27. An electrical connection is thereby established between the block 12 and a back electrode (not shown), for example, formed on the semiconductor element 21 via the joining material 27.

The plurality of leads 3A, 3B, and 3C are used in order to fix the semiconductor laser device A1 to an electronic device or the like, and form power supply paths to the semiconductor laser chip 2. The plurality of leads 3A, 3B, and 3C are rod-like members made of Fe—Ni alloy and having a diameter of about 0.45 mm, for example. Also, the plurality of leads 3A, 3B, and 3C may be Au plated.

The lead 3A and the lead 3B are each inserted through a different one of the two lead through-holes 114. As shown in FIG. 3, the portion of the lead 3A on the forward side in the z direction projects forward in the z direction from the lead through-hole 114. Also, the larger portion of the lead 3A that is located on the backward side in the z direction projects from the base 11 backward in the z direction. The portion of the lead 3B on the forward side in the z direction projects slightly forward in the z direction from the lead through-hole 114 but by less than the projection length of the lead 3A. Also, the larger portion of the lead 3B that is located on the backward side in the z direction projects from the base 11 backward in the z direction. A region near the backward end of the lead 3A in the z direction is given as a terminal part 31A that is used when mounting the semiconductor laser device A1 to an electronic device or the like. Similarly, a region near the backward end of the lead 3B in the z direction is given as a terminal part 31B that is used when mounting the semiconductor laser device A1 to an electronic device or the like.

The length of the lead 3A is about 7.7 mm, for example. The length of the lead 3A that is accommodated in the lead through-hole 114 is about 0.5 mm, the length projecting forward in the z direction is about 0.7 mm, and the length projecting backward in the z direction is about 6.5 mm.

The length of the lead 3B is about 7.0 to 7.2 mm, for example. The length of the lead 3B that is accommodated in the lead through-hole 114 is about 0.5 mm, the length projecting forward in the z direction is about 0 to 0.2 mm, and the length projecting backward in the z direction is about 6.5 mm.

The lead 3C is, as shown in FIG. 4, joined to a surface of the base 11 that faces backward in the z direction, and is electrically connected to the stem 1. Also, in the present embodiment, the lead 3C overlaps with the block 12 of the stem 1 in the x direction and the y direction, as is evident from FIGS. 3 and 4. The length of the lead 3C is about 6.5 mm, for example. A region near the backward end of the lead 3C in the z direction is given as a terminal part 31C that is used when mounting the semiconductor laser device A1 to an electronic device or the like.

In the present embodiment, as shown in FIGS. 2 and 3, an insulating filler 17 fills the space between the leads 3A and 3B and the two lead through-holes 114. The insulating filler 17 fixes the lead 3A and the lead 3B to the base 11 of the stem 1, and functions to insulate the leads 3A and 3B from the stem 1. The insulating filler 17 is not particularly limited in terms of material, and, in the present embodiment, is made of glass.

As shown in FIGS. 1 and 2, the lead 3A is connected to the semiconductor laser chip 2 by the wire 5. More specifically, the lead 3A is connected by the wire 5 to a pad electrode (not shown) formed on the semiconductor element 21 of the semiconductor laser chip 2. The wire 5 is made of Au, for example. In the semiconductor laser chip 2, the wire 5 may be bonded to the pad electrode formed on the semiconductor element 21, or the wire 5 may be bonded to a pad formed on the submound 22. The lead 3C is electrically connected to the back electrode of the submound 22 of the semiconductor laser chip 2 via the stem and the joining material 27. According to such a configuration, in the semiconductor laser device A1, power supply paths to the semiconductor laser chip 2 are formed by the lead 3A and the lead 3C.

In the case where power is supplied to the semiconductor laser device A1 only for the purpose of causing the semiconductor laser chip 2 to emit light, a configuration that does not use the lead 3B as a power path can be adopted. The lead 3B may be used merely in order to mechanically fix the semiconductor laser device A1 to an electronic device. Alternatively, the lead 3B may be used as a power supply path to the semiconductor laser chip 2, or, in the case where the semiconductor laser device A1 is provided with a light receiving element (not shown), the lead 3B may be electrically connected to this light receiving element.

Next, the operation of the semiconductor laser device A1 will be described.

According to the present embodiment, part of semiconductor laser chip 2 is accommodated in the lead through-hole 114 in the stem 1. The amount by which the semiconductor laser chip 2 projects in the z direction from the base 11 of the stem 1 can thereby be reduced, even if the dimensions in the z direction are enlarged due to increasing the output of the semiconductor laser chip 2. Accordingly, higher output and miniaturization of the semiconductor laser device A1 can be achieved.

Also, as a result of the lead through-hole 114 passing through the base 11, heat that is generated when the semiconductor laser chip 2 emits light can be released on both sides of the base 11 in the z direction. Heat dissipation of the semiconductor laser chip 2 can thereby be promoted, which is advantageous in increasing the output of the semiconductor laser chip 2.

As shown in FIGS. 3 to 5, the forward end of the semiconductor laser chip 2 in the z direction is located further backward in the z direction than the forward end of the block 12 of the stem 1 in the z direction. When an object approaches from the front in the z direction at the time of manufacture, conveyance or use of the semiconductor laser device A1, the semiconductor laser chip 2 can thereby be prevented from being damaged by this object.

Also, the backward end of the semiconductor laser chip 2 in the z direction is located further forward in the z direction than the backward end of the chip through-hole 112 in the z direction. It is thereby possible, when mounting the semiconductor laser device A1 to an electronic device or the like, for example, to avoid one part of the circuit board of this electronic device colliding with the backward end of the semiconductor laser chip 2 in the z direction.

As a result of the supporting surface 121 of the block 12 being flush with the inner surface 113 of the chip through-hole 112, the semiconductor laser chip 2 can be supported over a longer area in the z direction. In particular, a configuration that joins the semiconductor laser chip 2 to both the supporting surface 121 and the inner surface 113 by the joining material 27 is suitable for more reliably fixing the semiconductor laser chip 2.

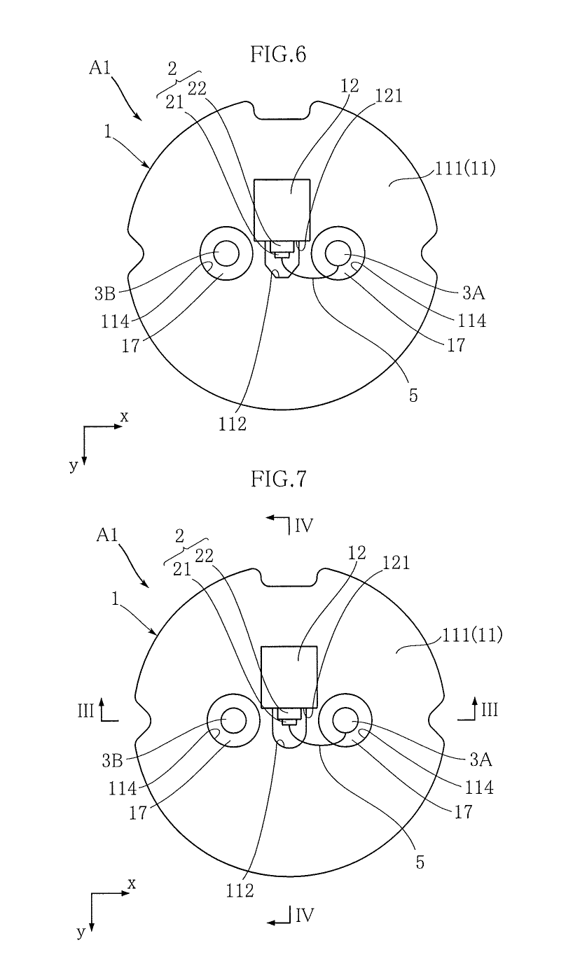

FIGS. 6 to 24 show modifications and other embodiments of the present invention. Note that in these figures, the same reference signs as the above embodiment are given to elements that are the same as or similar to the above embodiment.

FIGS. 6 and 7 are plan views showing modifications of the semiconductor laser device A1. In the modification shown in FIG. 6, the shape of the chip through-hole 112 as seen in the z direction is polygonal rather than rectangular. Also, in the modification shown in FIG. 7, the shape of the chip through-hole 112 as seen in the z direction is a combination of a semicircle and a rectangle. As is evident from these modifications, the shape of the chip through-hole 112 is not particularly limited as long as part of semiconductor laser chip 2 can be appropriately accommodated therein. This similarly applies to the embodiments that will be discussed below.

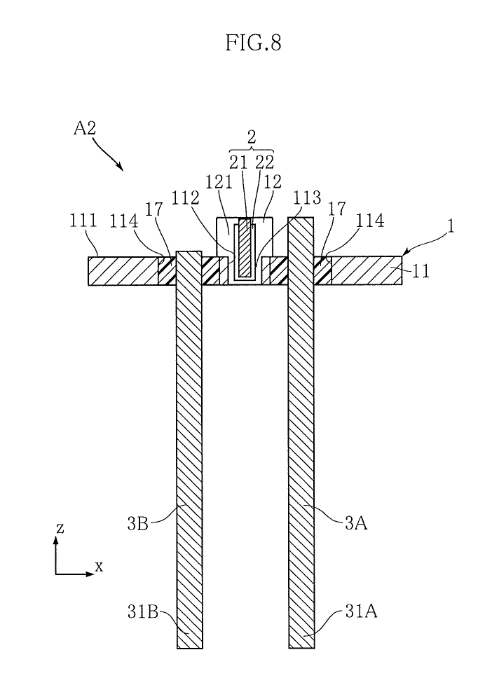

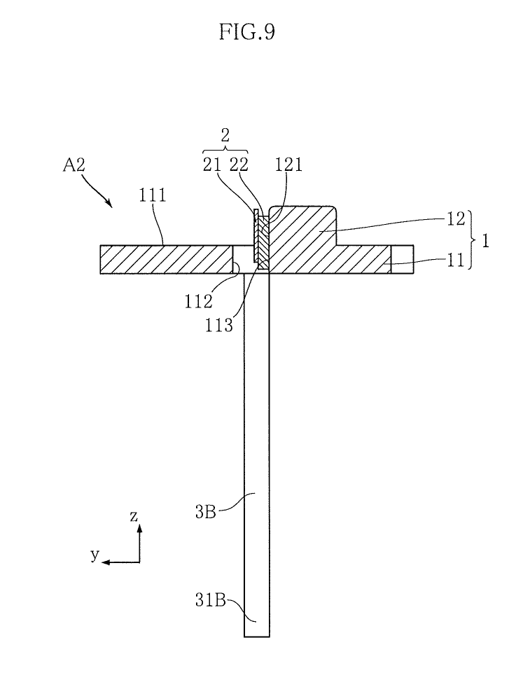

FIGS. 8 and 9 show a semiconductor laser device that is based on a second embodiment of the present invention. A semiconductor laser device A2 of the present embodiment differs from the abovementioned embodiment in that the lead 3A and the lead 3B are provided but the lead 3C is not provided.

The lead 3A and the lead 3B are also each similarly inserted through a different one of the two lead through-holes 114 in the present embodiment. Also, the insulating filler 17 fills the space between the leads 3A and 3B and the two lead through holes 114. The lead 3A and the lead 3B are connected to the semiconductor laser chip 2 by the two wires 5 mentioned above.

In the present embodiment, mounting of the semiconductor laser device A2 to an electronic device and power supply to the semiconductor laser chip 2 are performed using the lead 3A and the lead 3B. In the case where the abovementioned light receiving element is not provided, the semiconductor laser device A2 can be operated by the two leads 3A and 3B, and higher output and miniaturization of the semiconductor laser device A2 can also similarly be achieved according to the present embodiment. This also applies to the embodiments discussed below.

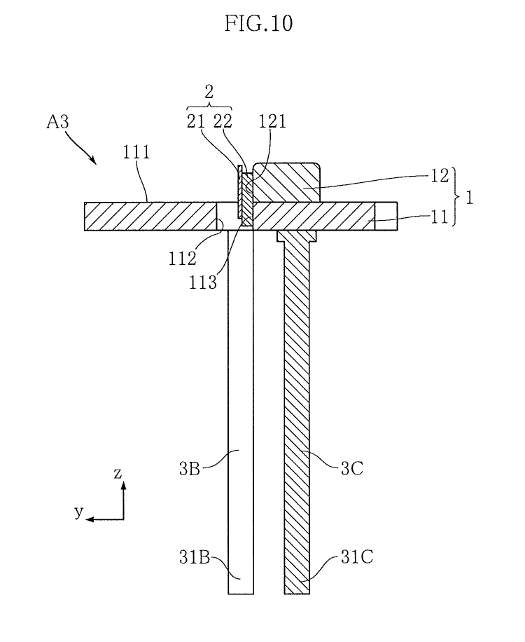

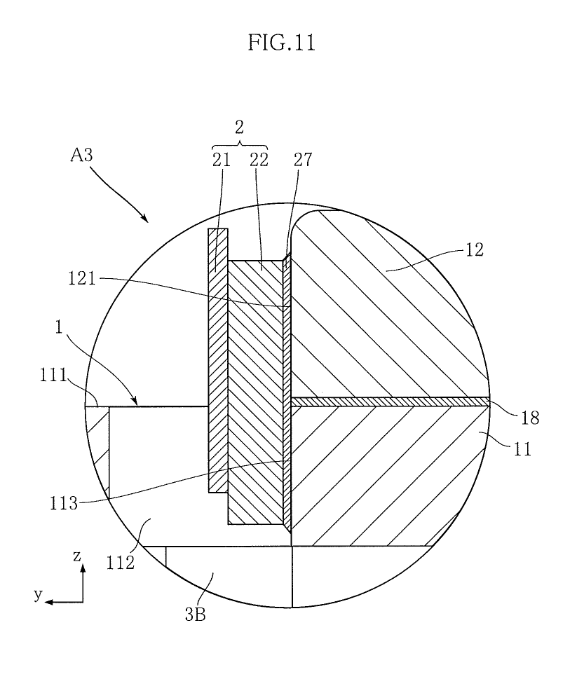

FIGS. 10 and 11 show a semiconductor laser device that is based on a third embodiment of the present invention. A semiconductor laser device A3 of the present embodiment differs from the above embodiments in the configuration of the stem 1.

In the present embodiment, the base 11 and the block are formed as separate elements to each other. The base 11 is joined to the block 12 by a joining material 18 as shown in FIG. 11. The base 11 is made of the abovementioned Fe or Fe alloy, for example. The block 12 may have a configuration made of Fe or Fe alloy, or may alternatively have a configuration made of Cu or Cu alloy. A paste containing a metal material, a joining alloy used in brazing, or a weld formed as a result of welding are given as examples of the joining material 18 that joins the base 11 to the block 12.

The supporting surface 121 of the block 12 is also similarly flush with the inner surface 113 of the chip through-hole 112 in the present embodiment. Also, the semiconductor laser chip 2 is joined to both the supporting surface 121 and the inner surface 113 by the joining material 27. Higher output and miniaturization of the semiconductor laser device A3 can also similarly be achieved according to such an embodiment.

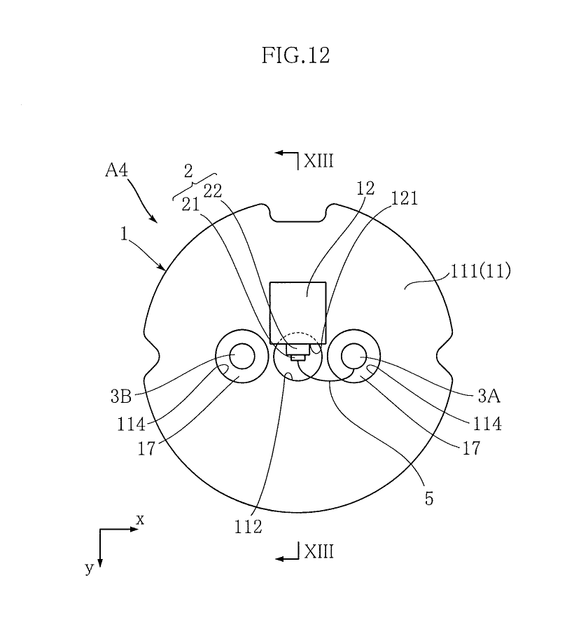

FIGS. 12 to 14 show a semiconductor laser device that is based on a fourth embodiment of the present invention. A semiconductor laser device A4 of the present embodiment differs in terms of the detailed structure, even though the basic configuration of the stem 1 is similar to the stem 1 of the semiconductor laser device A3.

The base 11 and the block 12 are also similarly formed as separate elements in the present embodiment. As shown in FIG. 12, the block 12 overlaps with part of the chip through-hole 112 in the base 11. Specifically, the chip through-hole 112 has a circular shape as seen in the z direction. The block 12 is disposed so as to cut off part of the chip through-hole 112 in an arc as seen in the z direction.

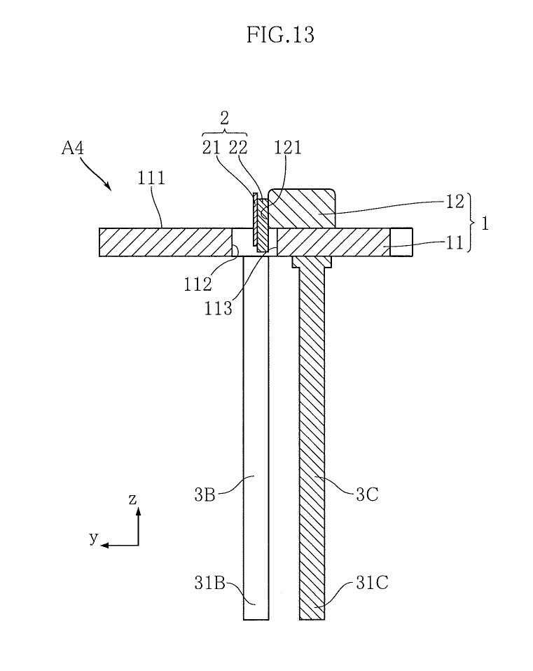

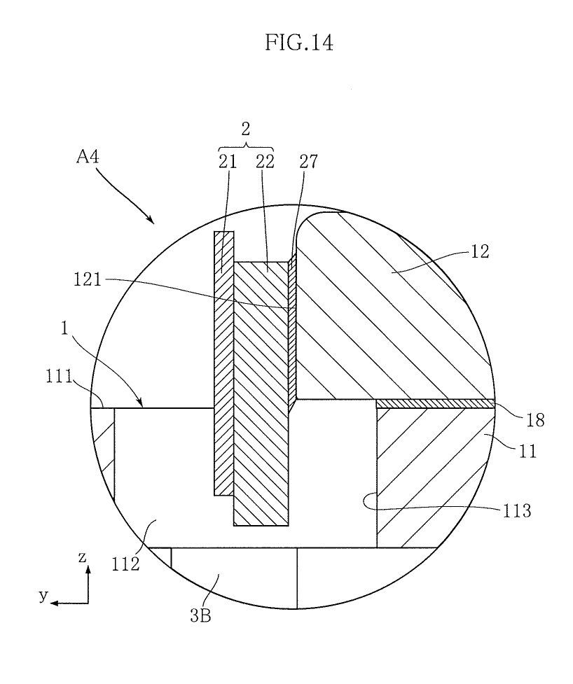

As shown in FIGS. 13 and 14, the supporting surface 121 of the block 12 is not flush with the inner surface 113 of the chip through-hole 112. As shown in FIG. 14, in the present embodiment, the supporting surface 121 of the block 12 juts out more inwardly of the chip through-hole 112 in the y direction than the inner surface 113 of the chip through-hole 112. Also, in the present embodiment, the semiconductor laser chip 2 is joined to only the supporting surface 121 of the block 12 by the joining material 27, and is not joined to the inner surface 113 of the chip through-hole 112. Higher output and miniaturization of the semiconductor laser device A4 can also similarly be achieved according to such an embodiment.

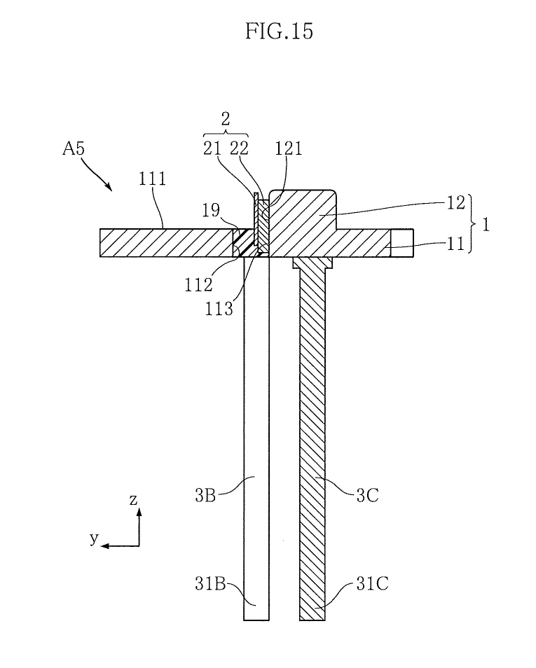

FIG. 15 shows a semiconductor laser device that is based on a fifth embodiment of the present invention. A semiconductor laser device A5 of the present embodiment is provided with a filler 19, and the remaining configuration is in common with the abovementioned semiconductor laser device A1.

The filler 19 fills the space between the chip through-hole 112 and the semiconductor laser chip 2. An insulating resin or glass can be appropriately employed as such a filler 19. Higher output and miniaturization of the semiconductor laser device A5 can also similarly be achieved according to the present embodiment. Also, the semiconductor laser chip 2 can be more reliably protected by the filler 19. Also, the effect of promoting heat dissipation from the semiconductor laser chip 2 can be expected. Note that a configuration having the filler 19 can also be employed as appropriate in the abovementioned semiconductor laser devices A2 to A4.

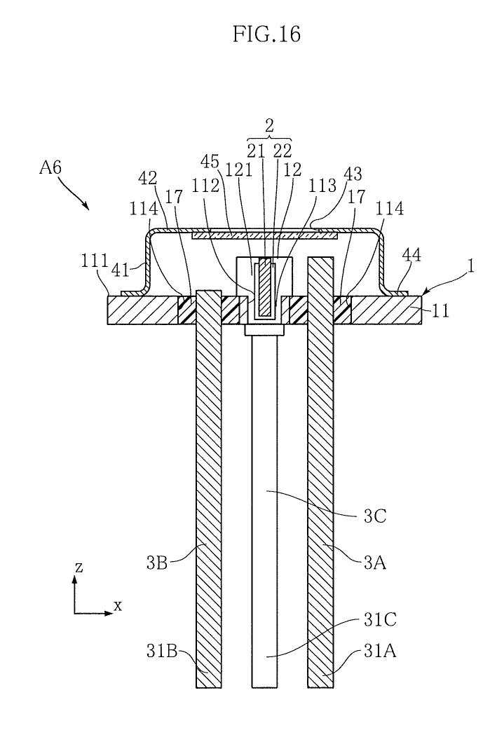

FIG. 16 shows a semiconductor laser device that is based on a sixth embodiment of the present invention. A semiconductor laser device A6 of the present embodiment is provided with a cap 4, and the remaining configuration is in common with the abovementioned semiconductor laser device A1.

The cap 4 covers the semiconductor laser chip 2 and the block 12, and is fixed to the main surface 111 of the base 11 of the stem 1. The cap 4 has a body part 41, a top part 42, a flange part 44 and a transparent cover 45. The body part 41 surrounds the semiconductor laser chip 2 and the block 12 in a direction at a right-angle to the z direction, and has a circular shape, for example.

The top part 42 is connected to the forward end of the body part 41 in the z direction, and is located forward in the z direction relative to the semiconductor laser chip 2. In the present embodiment, the top part 42 has a circular shape. An opening 43 is formed in the top part 42. The opening 43 is for allowing light from the semiconductor laser chip 2 to pass. In the present embodiment, the opening 43 has a circular shape.

The flange part 44 is connected to a backward portion of the body part 41 in the z direction, and extends outward along an xy plane. The flange part 44 has an annular shape, for example, and is fixed to the main surface 111 of the base 11 by welding, a joining material or the like.

The transparent cover 45 closes the opening 43 and transmits light from the semiconductor laser chip 2. The transparent cover 45 is made of a material that is transparent to light from the semiconductor laser chip 2. In the case where such a transparent cover 45 is provided, light from the semiconductor laser device A6 can be selectively emitted to a comparatively narrow area. In the present embodiment, the transparent cover 45 is attached to the lower surface of the top part 42 of the cap 4 in the figure.

Higher output and miniaturization of the semiconductor laser device A6 can also similarly be achieved according to such an embodiment. Also, the semiconductor laser chip 2 can be more reliably protected by the cap 4. Also, providing the transparent cover 45 enables light emitted from the semiconductor laser device A6 to be formed as light having comparatively high directivity.

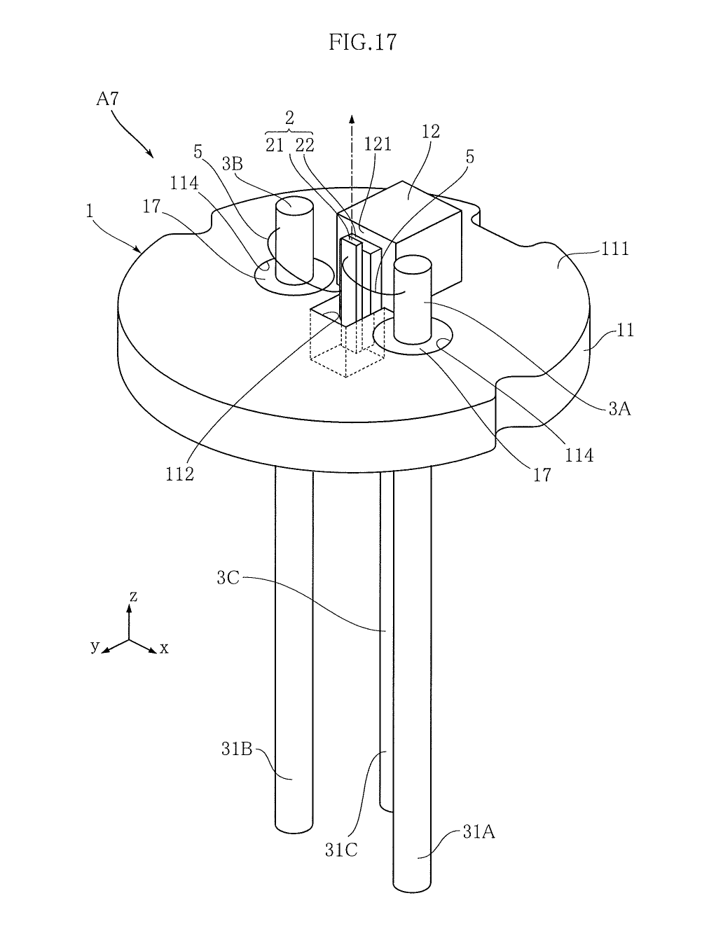

FIG. 17 shows a semiconductor laser device that is based on a seventh embodiment of the present invention. A semiconductor laser device A7 of the present embodiment differs from the abovementioned embodiments with respect to the power supply path to the semiconductor laser chip 2.

In the present embodiment, a portion on the forward side of the lead 3B in the z direction greatly projects from the main surface 111 of the base 11 of the stem 1. One wire 5 is connected to the semiconductor laser chip 2 and the lead 3A, and another wire 5 is further connected to the semiconductor laser chip 2 and the lead 3B. More specifically, the pad electrode formed on the semiconductor element 21 of the semiconductor laser chip 2 is connected to the lead 3A by a wire 5. On the other hand, a pad electrode (not shown) formed on the submound 22 of the semiconductor laser chip 2 is connected to the lead 3B by a wire 5. In the present embodiment, the lead 3C is not electrically connected to the semiconductor laser chip 2, and is used in order to mechanically fix the semiconductor laser device A7, for example.

Higher output and miniaturization of the semiconductor laser device A7 can also similarly be achieved according to such an embodiment. The form of the power supply path of the present embodiment is, of course, applicable as appropriate to the abovementioned semiconductor laser devices A2 to A6 and semiconductor laser devices A8 to A11.

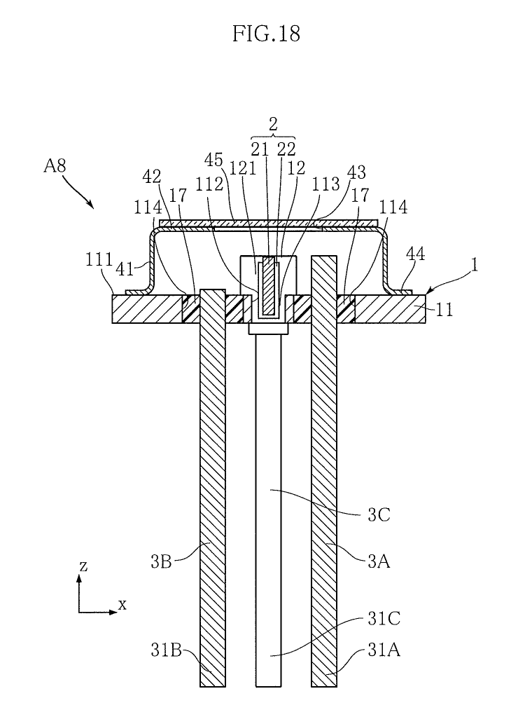

FIG. 18 shows a semiconductor laser device that is based on an eighth embodiment of the present invention. A semiconductor laser device A8 of the present embodiment has a transparent cover 45, similarly to the abovementioned semiconductor laser device A7. In the present embodiment, the transparent cover 45 is attached to the upper surface of the top part 42 of the cap 4 in the figure. Also, the dimensions of the transparent cover 45 as seen in the z direction are substantially the same as the top part 42 of the cap 4.

Higher output and miniaturization of the semiconductor laser device A8 can also similarly be achieved according to such an embodiment. Also, the semiconductor laser chip 2 can be more reliably protected by the cap 4. Also, providing the transparent cover 45 enables light emitted from the semiconductor laser device A6 to be formed as light having comparatively high directivity.

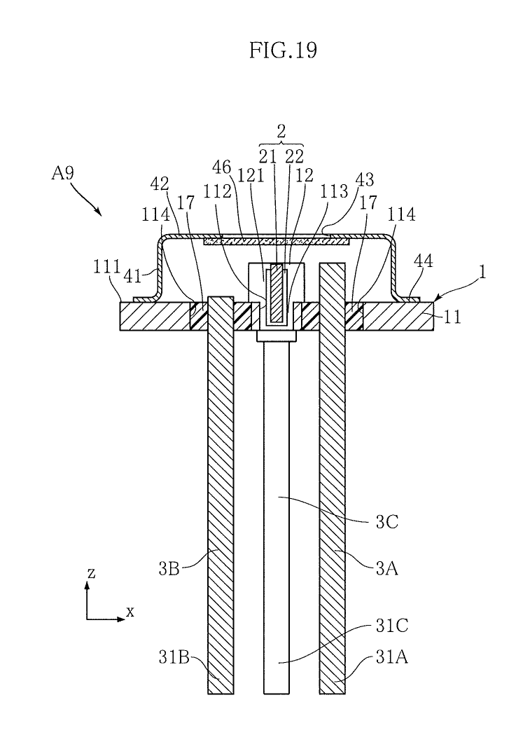

FIG. 19 shows a semiconductor laser device that is based on a ninth embodiment of the present invention. In a semiconductor laser device A9 of the present embodiment, the cap 4 has a diffusion cover 46 instead of the abovementioned transparent cover 45.

The diffusion cover 46 is formed by a material that transmits and diffuses light from the semiconductor laser chip 2. Also, in the present embodiment, the diffusion cover 46 is attached to the lower surface of the top part 42 of the cap 4 in the figure.

Higher output and miniaturization of the semiconductor laser device A9 can also similarly be achieved according to such an embodiment. Also, the semiconductor laser chip 2 can be more reliably protected by the cap 4. Also, providing the diffusion cover 46 enables the spread angle of light emitted from the semiconductor laser device A9 to be controlled.

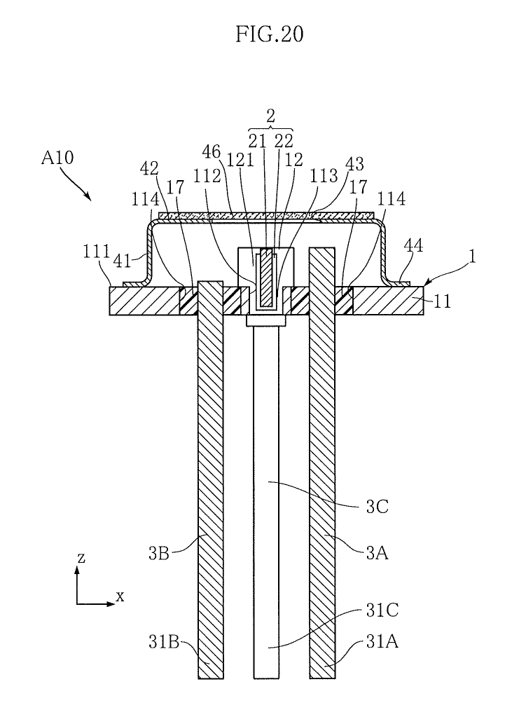

FIG. 20 shows a semiconductor laser device that is based on a tenth embodiment of the present invention. A semiconductor laser device A10 of the present embodiment has a diffusion cover 46, similarly to the abovementioned semiconductor laser device A9. In the present embodiment, the diffusion cover 46 is attached to the upper surface of the top part 42 of the cap 4 in the figure. Also, the dimensions of the diffusion cover 46 as seen in the z direction are substantially the same as the top part 42 of the cap 4.

Higher output and miniaturization of the semiconductor laser device A10 can also similarly be achieved according to such an embodiment. Also, the semiconductor laser chip 2 can be more reliably protected by the cap 4. Providing the diffusion cover 46 enables the spread angle of light emitted from the semiconductor laser device A9 to be controlled.

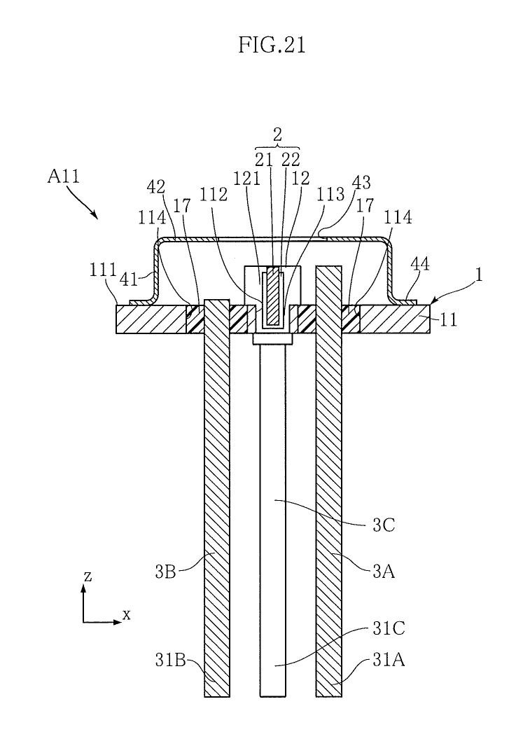

FIG. 21 shows a semiconductor laser device that is based on an eleventh embodiment of the present invention. A semiconductor laser device A11 of the present embodiment differs from the semiconductor laser devices A6, A8 to A10 with respect to the configuration of the abovementioned cap 4.

In the present embodiment, the opening 43 of the cap 4 is not covered by either the transparent cover 45 or the diffusion cover 46. A configuration in which the inner space of the cap 4 communicates with the outside is thus adopted. Higher output and miniaturization of the semiconductor laser device A10 can also similarly be achieved according to such an embodiment. Also, the semiconductor laser chip 2 can be protected by the cap 4.

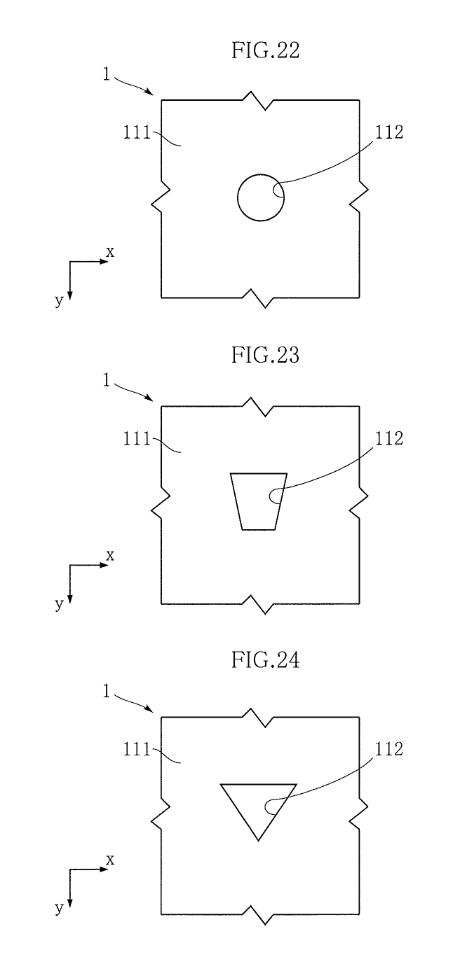

FIG. 22 shows a modification of the chip through-hole 112 of the stem 1. In the modification shown in FIG. 22, the chip through-hole 112 has a circular shape as seen in the z direction. In the modification shown in FIG. 23, the chip through-hole 112 has a trapezoidal shape as seen in the z direction. In the modification shown in FIG. 24, the chip through-hole 112 has a triangular shape as seen in the z direction. The chip through-holes 112 of these modifications all have a size and shape that can appropriately accommodate the semiconductor laser chip 2. As is evident from these modifications, the chip through-hole 112 of the present invention can take various shapes as long as the semiconductor laser chip 2 can be appropriately accommodated.

Also, a configuration in which light detection means is provided downward in the z direction relative to the semiconductor laser chip 2 and the chip through-hole 112 in FIG. 3, for example, may be adopted. This light detection means, by receiving light that travels downward in the z direction from the semiconductor laser chip 2, outputs an electrical signal that depends on the brightness of this light. Examples of such light detection means include a photo-diode.

According to such configuration, so-called feedback control can be performed on power that is supplied to the semiconductor laser chip 2, using the output of the light detection means. Also, part of the light that travels upward from the semiconductor laser chip 2 in the figure does not need to be used in order to perform feedback control. The luminance of light emitted from semiconductor laser device can thus be increased, while performing feedback control. Such a configuration can, of course, also be applied to any of the abovementioned semiconductor laser devices A1 to A11.

The semiconductor laser device according to the present invention is not limited to the abovementioned embodiments. Various design modifications can be made to the specific configurations of the respective parts of the semiconductor laser device according to the present invention.

1. A semiconductor laser device comprising:
a semiconductor laser chip configured to emit laser light forward in an emission direction; and
a stem including a tabular base a thickness direction of which is in the emission direction,
wherein the base is formed with a chip through-hole that passes through in the thickness direction, and
a part of the semiconductor laser chip is accommodated in the chip through-hole.

2. The semiconductor laser device according to claim 1, wherein the stem has a block projecting in the emission direction from the base, and
the semiconductor laser chip is supported by the block.

3. The semiconductor laser device according to claim 2, wherein a forward end of the semiconductor laser chip in the emission direction is located further backward in the emission direction than a forward end of the block in the emission direction.

4. The semiconductor laser device according to claim 2, wherein a backward end of the semiconductor laser chip in the emission direction is located further forward in the emission direction than a backward end of the chip through-hole in the emission direction.

5. The semiconductor laser device according to claim 2, wherein the base and the block are integrally formed with each other.

6. The semiconductor laser device according to claim 5, wherein the base and the block are made of Fe or Fe alloy.

7. The semiconductor laser device according to claim 2, wherein the base and the block are formed as separate elements.

8. The semiconductor laser device according to claim 7, wherein the base is made of Fe or Fe alloy.

9. The semiconductor laser device according to claim 7, wherein the block is made of Cu or Cu alloy.

10. The semiconductor laser device according to claim 2, wherein the block has a supporting surface that supports the semiconductor laser chip.

11. The semiconductor laser device according to claim 10, wherein the supporting surface is parallel to the emission direction.

12. The semiconductor laser device according to claim 10, wherein the chip through-hole has a rectangular shape as seen in the emission direction.

13. The semiconductor laser device according to claim 12, wherein an inner surface of the chip through-hole is flush with the supporting surface.

14. The semiconductor laser device according to claim 10, wherein the semiconductor laser chip is joined to the stem by a joining material.

15. The semiconductor laser device according to claim 14, wherein the semiconductor laser chip is joined to the supporting surface of the block by the joining material.

16. The semiconductor laser device according to claim 14, wherein the semiconductor laser chip is joined to the inner surface of the chip through-hole by the joining material.

17. The semiconductor laser device according to claim 10, wherein the semiconductor laser chip is made up of a semiconductor element made of a semiconductor material and a submount on which the semiconductor element is mounted.

18. The semiconductor laser device according to claim 17, wherein the submount is made of Si or AlN.

19. The semiconductor laser device according to claim 1, comprising one or more leads that are supported by the stem, project backward in the emission direction, and are electrically connected to the semiconductor laser chip.

20. The semiconductor laser device according to claim 19, wherein the base has a through-hole through which the lead is inserted.

21. The semiconductor laser device according to claim 20, wherein an insulating filler fills a space between the lead through-hole and the lead.

22. The semiconductor laser device according to claim 21, wherein the insulating filler is made of glass.

23. The semiconductor laser device according to claim 19, wherein the lead is made of Fe—Ni alloy or Fe—Ni—Co alloy.

24. The semiconductor laser device according to claim 23, wherein the lead is Au plated.

25. The semiconductor laser device according to claim 19, comprising a wire electrically connecting the lead to the semiconductor laser chip.

26. The semiconductor laser device according to claim 25, wherein the wire is made of Au.

27. The semiconductor laser device according to claim 1, comprising a cap that is fixed to the base, covers the semiconductor laser chip, and has an opening that allows light from the semiconductor laser chip to pass.

28. The semiconductor laser device according to claim 27, wherein the cap has a body part surrounding the semiconductor laser chip in a direction at a right-angle to the emission direction, and a top part connected to a forward portion of the body part in the emission direction.

29. The semiconductor laser device according to claim 28, wherein the cap has a flange part that is connected to a backward portion of the body part in the emission direction and is fixed to the base.

30. The semiconductor laser device according to claim 28, wherein the opening is formed in the top part.

31. The semiconductor laser device according to claim 27, wherein the cap includes a cover that closes the opening and through which light from the semiconductor laser chip passes.

32. The semiconductor laser device according to claim 31, wherein the cover is transparent.

33. The semiconductor laser device according to claim 31, wherein the cover transmits and diffuses light from the semiconductor laser chip.
